(19) United States
(12) Patent Application Publication
(10) Pub. No.: US 2008/0056041 A1
(43) Pub. Date: Mar. 6, 2008

(54) MEMORY CIRCUIT

(76) Inventors: Corvin Liaw, Munich (DE); Michael Markert, Augsburg (DE); Stefan Dietrich, Tuerkenfeld (DE); Milena Dimitrova, Unterhaching (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/469,746

(22) Filed: Sep. 1, 2006

(51) Int. Cl. G11C 7/02

(52) U.S. Cl. 365/208

(57) ABSTRACT

A memory circuit comprises a plurality of parallel bit-lines connected to a plurality of memory cells, a plurality of sense amplifiers connected to the bit-lines and a plurality of switches each of which being connected to a respective pair of bit-lines out of the plurality of bit-lines for switchably short-circuiting the respective pair of bit-lines. The bit-lines of the respective pair of bit-lines are connected to two different sense amplifiers, and the bit-lines of the respective pair of bit-lines are adjacent to a further bit-line disposed between the bit-lines of the respective pair of bit-lines.

### BACKGROUND OF THE INVENTION

1. Field of the Invention

The present invention relates to a memory circuit, a memory device and a method of operating a memory circuit.

2. Description of the Related Art

Memory circuits comprising large numbers of memory cells are part of a large variety of microelectronic devices as well as of dedicated memory devices. The rapidly growing number of applications of digital information technology in virtually all fields of technology comes along with a similarly growing demand for high-speed and high-capacity memory circuits.

There are many different technologies of storing information in memory cells. In memory circuits with resistive storage elements as well as in some other kinds of memory circuits, the procedure of reading data from memory cells includes comparing the electrostatic potential or the charge on a bit-line with a reference potential or reference charge, respectively. For example in CBRAM (Conductive Bridging RAM) technology, the reference potential is usually an arithmetic mean of a read voltage V_{read} and a plate voltage, or discharge voltage V_{PL}. One way of generating the reference potential is to provide the two different well-defined potentials to two different bit-lines and then short-circuit these bit-lines.

### SUMMARY OF THE INVENTION

The present invention provides advantages for an improved memory circuit, an improved memory device and an improved method of operating a memory circuit.

One embodiment of the present invention provides a memory circuit comprising a plurality of parallel bitlines connected to a plurality of memory cells, a plurality of sense amplifiers connected to the bitlines, a plurality of switches, each switch being connected to a respective pair of bit-lines out of the plurality of bitlines for switchably short-circuiting the respective pair of bit-lines, the bit-lines of the respective pair of bit-lines being connected to two different sense amplifiers, and the bit-lines of the respective pair of bit-lines being respectively adjacent to a further bit-line between the bit-lines of the respective pair of bit-lines.

Another embodiment of the present invention provides a memory circuit comprising a plurality of memory cells arranged in a two-dimensional array, a plurality of parallel bit-lines connected to the plurality of memory cells, a plurality of sense amplifiers connected to the plurality of bit-lines, and a plurality of switches each of which is connected to a respective pair of bit-lines out of the plurality of bit-lines for switchably short-circuiting the respective pair of bit-lines, wherein a first group of bit-lines out of the plurality of bit-lines is connected solely to sense amplifiers arranged at a first side of the array, a second group of bit-lines out of the plurality of bit-lines is connected solely to sense amplifiers arranged at a second side of the array, and each respective pair of bit-lines connected to a switch out of the plurality of switches consists of one bit-line out of the first group of bit-lines and one bit-line out of the second group of bit-lines.

In still another embodiment of the present invention, a method of operating a memory circuit is provided. The method comprises selecting a first bit-line connected to a memory cell to be read or written or refreshed, wherein the first bit-line is connected to a first sense amplifier; applying a first predetermined potential to a second bit-line adjacent to the first bit-line, wherein the second bit-line is connected to the first sense amplifier; applying a second predetermined potential to a third bit-line adjacent to the first bit-line, wherein the third bit-line is connected to a second sense amplifier; short-circuiting the second and third bit-lines; and reading data from the memory cell.

In yet another embodiment of the present invention, a method of operating a memory circuit comprising an array of memory cells is provided. The method comprises selecting a first bit-line connected to a memory cell to be read or written or refreshed, wherein the first bit-line is connected to a first sense amplifier arranged at a first side of the array; applying a first predetermined potential to a second bit-line connected to the first sense amplifier; applying a second predetermined potential to a third bit-line connected to a second sense amplifier arranged at a second side of the array; short-circuiting the second and third bit-lines; and reading data from the memory cell.

### BRIEF DESCRIPTION OF THE DRAWINGS

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIG. 1 shows a schematic circuit diagram of a conventional memory circuit.

FIG. 2 shows a another schematic circuit diagram of the conventional memory circuit shown on FIG. 1.

FIG. 3 shows a schematic circuit diagram of a memory circuit according to a first embodiment of the present invention.

FIG. 4 shows a schematic circuit diagram of a memory circuit according to a second embodiment of the present invention.

FIG. 5 shows a schematic circuit diagram of a memory device according to a third embodiment of the present invention.

FIG. 6 shows a schematic flow chart of a method according to another embodiment of the present invention.

### DETAILED DESCRIPTION OF THE PREFERRED EMBODIMENT

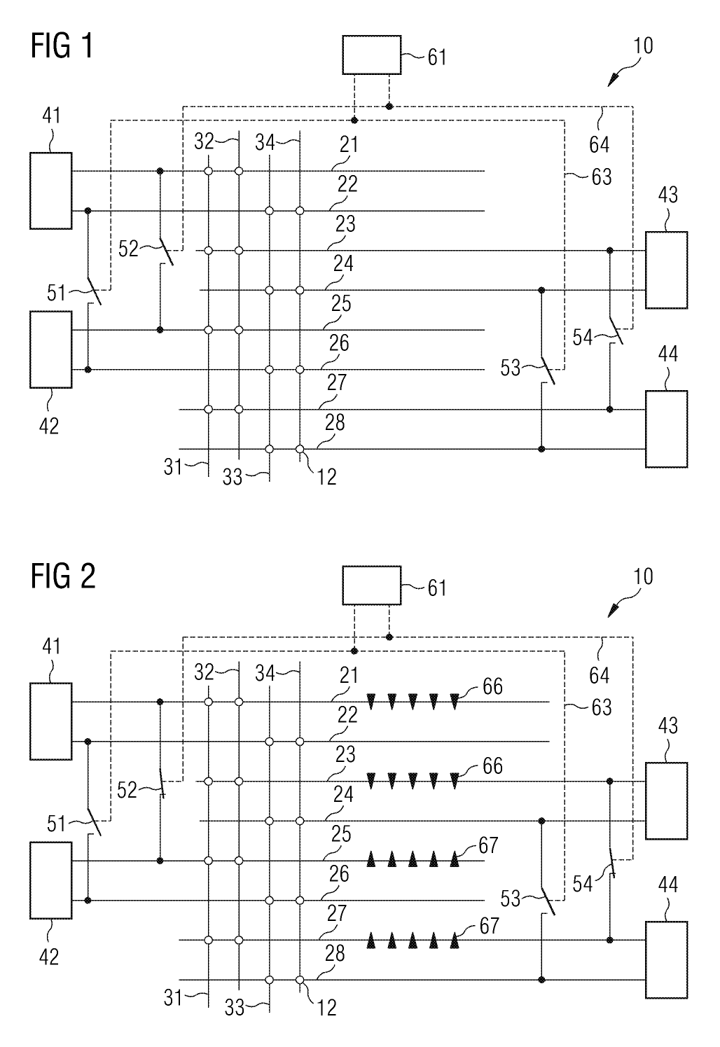

FIG. 1 shows a schematic circuit diagram of a conventional memory circuit 10. The memory circuit 10 comprises a plurality of memory cells 12 which are schematically represented by circles. Although the present invention may be used for other storage technologies and other types of memory cells, too, the subsequent description of the conventional memory circuit 10 and of the embodiments of the present invention refers to the CBRAM technology.

In a CBRAM memory circuit, each memory cell 12 may comprise a selection transistor and a resistive storage element. A first terminal of the resistive storage element is connected to a conductive member (usually called plate) providing a plate voltage V_{PL} (all voltages with respect to a predefined reference potential). The other terminal of the resistive storage element is connected to the source drain area of the selection transistor. The resistive storage element provides (at least) two resistance states, a low resistance state and a high resistance state representing respectively either a logical 0 and a logical 1.

Further, the memory circuit 10 comprises a plurality of parallel bit-lines 21, 22, 23, 24, 25, 26, 27, 28 and a plurality of parallel word-lines 31, 32, 33, 34. The memory cells 12 are arranged at cross points of the bit-lines and the word-lines.

Furthermore, the memory circuit 10 comprises a plurality of sense amplifiers 41, 42, 43, 44 each of which is connected to two bit-lines 21, 22, 23, 24, 25, 26, 27, 28. For each sense amplifier 41, 42, 43, 44, one bit-line connected to the sense amplifier is called a true bit-line and the other bit-line connected to the same amplifier is called the complement bit-line. In the following, the bit-lines 21, 23, 25, 27 are called true bit-lines, and the bit-lines 22, 24, 26, 28 are called complement bit-lines. However, the nomenclature could be the other way round as well.

Furthermore, the memory circuit 10 comprises a plurality of switches 51, 52, 53 and 54, each of which is connected to a respective pair of bit-lines 22, 26; 21, 25; 24, 28; 23, 27, for switchably short-circuiting the respective pair of bit-lines. Each of the plurality of switches 51, 52, 53, 54 is either connected to two true bit-lines 21, 23, 25, 27 or connected to two complement bit-lines 22, 24, 26, 28. A controller 61 is connected operatively to the switches 51, 52, 53, 54 via control lines 63, 64.

Before or preferably during any access to a memory cell 12 connected to a true bit-line 21, 23, 25, 27, a reference potential is provided to the corresponding complement bit-line 22, 24, 26, 28 connected to the same sense amplifier. Before or preferably during any access to a memory cell 12 connected to a complement bit-line 22, 24, 26, 28, a reference potential is provided to the corresponding true bit-line 21, 23, 25, 27, connected to the same sense amplifier. The reference potential is usually an arithmetic mean of a read voltage V_{read} and a plate voltage V_{PL} or of any other first and second predetermined potentials.

For an access to one or several memory cells 12 connected to a true bit-line 21, 23, 25, 27, the first predetermined potential is impressed to the complement bit-lines 22, 24, and the second predetermined potential is impressed to the complement bit-lines 26, 28. Thereafter, the controller 61 closes the switches 51, 53 thereby short-circuiting the pair of complement bit-lines 22, 26 and short-circuiting the pair of complement bit-lines 24, 28. As a result, the complement bit-lines 22, 24, 26, 28 are tuned to an arithmetic mean potential Vₘₑₐₙ between the first and second predetermined potentials, i.e. between the plate potential V_{PL} and the read voltage V_{read}.

During or after the generation of the reference potential, the respective one of the plurality of word-lines 31, 32 is activated in order to connect the resistive storage element of the respective memory cells 12 to the true bit-lines 21, 23, 25, 27, and the read voltage V_{read} is provided to the true bit-lines 21, 23, 25, 27.

In one embodiment, the read voltage V_{read} is provided to the true bit-lines 21, 23, 25, 27 for a short period of time. After this short period of time, the voltage at each of the true bit-lines 21, 23, 25, 27 is a sense voltage indicating the resistance state of the respective resistive storage element. The sense voltage rapidly declines to the plate voltage V_{PL} when the respective resistive storage element is in a low resistance state. When the respective resistive storage element is in a high resistance state, the sense voltage slowly declines to the plate voltage V_{PL}.

The data stored in the respective resistive storage element is read by comparing the sense voltage at the respective true bit-line 21, 23, 25, 27 and the mean potential Vₘₑₐₙ at a corresponding complement bit-line 22, 24, 26, 28 by means of the respective sense amplifier 41, 42, 43, 44 connected to the respective true bit-line 21, 23, 25, 27 and to the corresponding complement bit-line 22, 24, 26, 28.

For an access to one or several memory cells 12 connected to a complement bit-line 22, 24, 26, 28, the first predetermined potential is impressed to the true bit-lines 21, 25, and the second predetermined potential is impressed to the true bit-lines 23, 27. Thereafter, the controller 61 closes the switches 52, 54 thereby short-circuiting the pair of true bit-lines 21, 25 and short-circuiting the pair of true bit-lines 23, 27. As a result, the true bit-lines 21, 23, 25, 27 are tuned to an arithmetic mean potential Vₘₑₐₙ between the first and second predetermined potentials, i.e. between the plate potential V_{PL} and the read voltage V_{read}.

During or after the generation of the reference potential, the respective one of the plurality of word-lines 33, 34 is activated in order to connect the resistive storage element of the respective memory cells 12 to the complement bit-lines 22, 24, 26, 28, and the read voltage V_{read} is provided to the complement bit-lines 22, 24, 26, 28.

In one embodiment, the read voltage V_{read} is provided to the complement bit-lines 22, 24, 26, 28 for a short period of time. After this short period of time, the voltage at each of the complement bit-lines 22, 24, 26, 28 is a sense voltage indicating the resistance state of the respective resistive storage element. The sense voltage rapidly declines to the plate voltage V_{PL} when the respective resistive storage element is in a low resistance state. When the respective resistive storage element is in a high resistance state, the sense voltage slowly declines to the plate voltage V_{PL}.

The data stored in the respective resistive storage element is read by comparing the sense voltage at the respective complement bit-line 22, 24, 26, 28 and the mean potential Vₘₑₐₙ at a corresponding true bit-line 21, 23, 25, 27 by means of the respective sense amplifier 41, 42, 43, 44 connected to the respective complement bit-line 22, 24, 26, 28 and to the corresponding true bit-line 21, 23, 25, 27.

As already described above, the read voltage V_{read} may be provided to the respective bit-line for a first predetermined short period of time. A second predetermined short period of time later, the storage state of the respective resistive storage element is sensed by sensing the voltage or potential difference between the respective bit-line and a corresponding bit-line providing the reference potential. In CBRAM technology, the resistance values of a resistive storage element in the high and low resistance states differ by several orders of magnitude. Therefore, the second predetermined period of time can be set and usually is set to such a value that the sense voltage at the moment it is detected by the sense amplifier either essentially equals the read voltage V_{read} (when the resistive storage element is in the high resistance state) or essentially equals the plate voltage V_{PL} (when the resistive storage element is in the low resistance state).

As an alternative, the respective bit-line connected to the memory cell to be read is still connected to the read voltage source when the respective sense amplifier reads the stored data by sensing the potential difference. In this case, when a resistive storage element of a memory cell activated by the respective active word-line is in the high resistance state, the read voltage V_{read} is maintained at the respective bit-line. When a resistive storage element of a memory cell activated by the respective active word-line is in the low resistance state, the potential of the respective bit-line is pulled to the plate voltage V_{PL}. For this alternative reading procedure, the internal resistance should provide an appropriate level between the resistance levels of the resistive storage element in the low and high resistance states.

In one embodiment, the impression of the predetermined potentials to the bit-lines is controlled by the controller 61 via control lines, switches and sources providing the potentials, wherein these lines, switches and sources are not displayed in FIG. 1. Alternatively, the impression of the predetermined potential to the bit-lines is controlled by other sub-circuits or sub-devices of the memory circuit 10.

FIG. 2 shows the memory circuit described above with reference to FIG. 1. The capacitive coupling between the bit-lines is now discussed for the above described case of an access to memory cells 12 connected to the complement bit-lines 22, 24, 26, 28. The read voltage V_{read} is impressed to the true bit-lines 21, 23, and the plate voltage V_{PL} is impressed to the true bit-lines 25, 27. When the switches 52, 54 are closed, the potential of the bit-lines 21, 23 drops from V_{read} to Vₘₑₐₙ (indicated by the arrows 66) while the potential of the bit-lines 25, 27 rises from V_{PL} to Vₘₑₐₙ (indicated by the arrows 67).

The bit-line 22 is arranged between two bit-lines 21, 23, the potential of which is falling from V_{read} to Vₘₑₐₙ. The bit-line 26 is arranged between two bit-lines 25, 27, the potential of which is rising from V_{PL} to Vₘₑₐₙ. Thereby, the potential of the bit-line 22 and the potential of the bit-line 26 are affected by capacitive coupling from the neighboring bit-lines 21, 23, 25, 27. This influence is detrimental and will even rise in future memory circuits because of the progressive miniaturization of microelectronic devices.

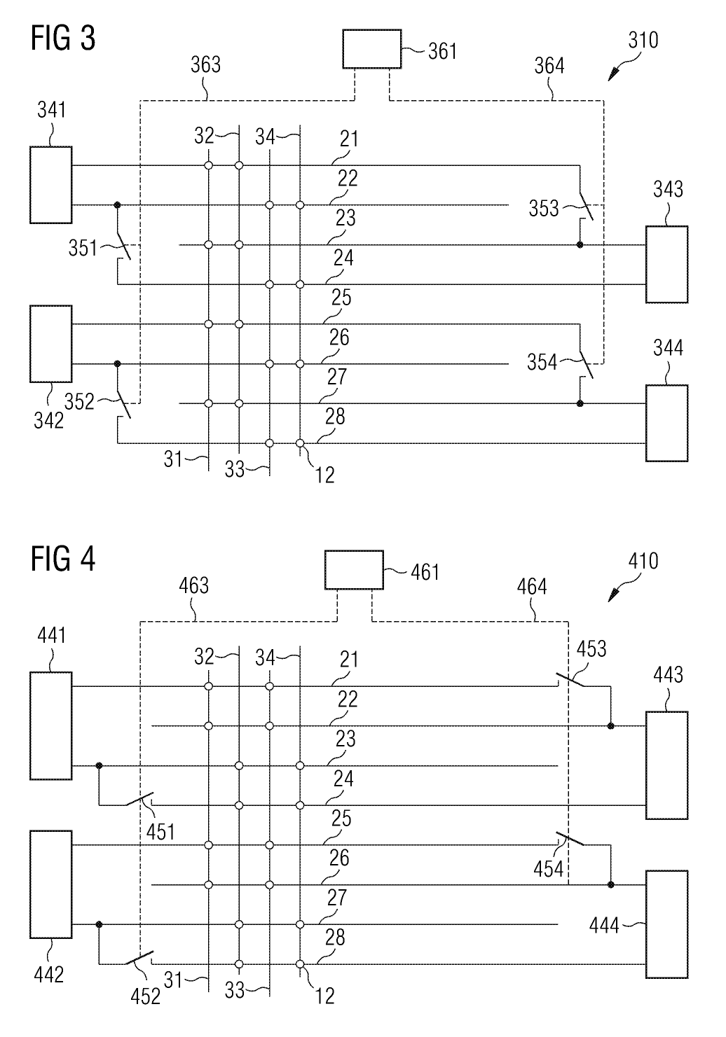

FIG. 3 is a schematic circuit diagram of a memory circuit 310 according to a first embodiment of the present invention. A plurality of memory cells 12 are arranged in a two-dimensional array at cross points of a plurality of parallel bit-lines 21, 22, 23, 24, 25, 26, 27, 28 and a plurality of parallel word-lines 31, 32, 33, 34. Each memory cell 12 is schematically represented by a circle. A plurality of sense amplifiers 341, 342, 343, 344 are provided at two opposite sides or edges of the array of memory cells. Each sense amplifier 341, 342, 343, 344 is connected to two bit-lines 21, 22, 23, 24, 25, 26, 27, 28 and each bit-line is connected to one sense amplifier.

Similar to the memory circuit described above with reference to FIG. 1, the memory circuit 310 shown in FIG. 3 comprises a plurality of switches 351, 352, 353 and 354. Each switch 351, 352, 353, 354 is connected to a respective pair of bit-lines 22, 24; 26, 28; 21, 23; 25, 27, for switchably short-circuiting the respective pair of bit-lines. A controller 361 is connected operatively to the switches 351, 352, 353, 354 via control lines 363, 364.

The bit-lines of each respective pair of bit-lines 22, 24; 26, 28; 21, 23; 25, 27 are connected to two different sense amplifiers 341, 342, 343, 344. For example, considering switch 351, the first bit-line 22 connected to the switch 351 is connected to the sense amplifier 341, and the second bit-line 24 connected to the switch 351 is connected to the sense amplifier 343. In contrast to the memory circuit described above with reference to FIG. 1, in the memory circuit 310 described with reference to FIG. 3, the sense amplifiers 341, 343 connected to the pair of bit-lines 22, 24 connected to the switch 351 are arranged at different (more particular: opposite) sides or edges of the array of memory cells 12. The same is true for the other switches 352, 353, 354 and respective pairs of bit-lines 26, 28; 21, 23; 25, 27 and the respective sense amplifiers 341, 342, 343, 344.

The operation of the memory circuit 310 shown in FIG. 3 is quite similar to the above-described operation of the memory circuit shown in FIG. 1.

The embodiment described above with reference to FIG. 3 provides a number of advantages, in particular when compared to the memory circuit described above with reference to FIG. 1. As can be easily seen, any bit-line is always arranged between two bit-lines which are connected to different predetermined potentials with opposite potential difference to the mean potential Vₘₑₐₙ.

For example, before or while an access to one or several of the memory cells 12 connected to the word-line 31, the first predetermined potential is impressed to the bit-lines 22 and 26 and the second predetermined potential is impressed to the bit-lines 24 and 28. Thereby, the bit-line 23 is arranged between one bit-line (bit-line 22) with the first predetermined potential and one bit-line (bit-line 24) with the second predetermined potential; the bit-line 25 is arranged between one bit-line (bit-line 26) with the first predetermined potential and one bit-line (bit-line 24) with the second predetermined potential; and the bit-line 27 is arranged between one bit-line (bit-line 26) with the first predetermined potential and one bit-line (bit-line 28) with the second predetermined potential.

Similarly, in preparation of an access to one or several of the memory cells connected to one of the word-lines 33, 34, the first predetermined potential is impressed to the bit-lines 21, 25 and the second predetermined potential is impressed to the bit-lines 23 and 27. Thereby, the bit-line 22 is arranged between one bit-line (bit-line 21) with the first predetermined potential and one bit-line (bit-line 23) with the second predetermined potential; the bit-line 24 is arranged between one bit-line (bit-line 25) with the first predetermined potential and one bit-line (bit-line 23) with the second predetermined potential; and the bit-line 26 is arranged between one bit-line (bit-line 25) with the first predetermined potential and one bit-line (bit-line 27) with the second predetermined potential.

If this symmetry, i.e. the arrangement of each bit-line between two neighboring or adjacent bit-lines connected to different predetermined potentials, shall be provided for the outer most bit-lines 21, 28, too, additional dummy bit-lines not displayed in FIG. 2 need to be arranged at the edges of the array. Alternatively, no data are stored in the memory cells of the outer most bit-lines 21, 28.

This symmetry makes sure that the capacitive influences of neighboring bit-lines on any bit-line cancel out each other. The net effect of capacitive coupling between the bit-lines is zero.

A further advantage of the memory circuit 310 described above with reference to FIG. 3 is provided by the fact that only one control line 363, 364 needs to be provided at each side of the array. This reduces the required chip area and makes the design of the control lines 363, 364 relatively less complex.

A further advantage of the memory circuit 310 described above with reference to FIG. 3 is provided by the fact that the switches 351, 352, 353, 354 can be easily arranged and connected to the bit-lines without the need for any crossing with further bit-lines (compare, for example, switch 51 and bit-line 25, switch 52 and bit-line 22, switch 53 and bit-line 27, switch 54 and bit-line 24 in the memory circuit described with reference to FIG. 1).

FIG. 4 is a schematic circuit diagram of a memory circuit 410 according to a second embodiment of the present invention. The memory circuit 410 comprises a plurality of memory cells 12 arranged in an array at cross points of a plurality of parallel bit-lines 21, 22, 23, 24, 25, 26, 27, 28 and a plurality of parallel word-lines 31, 32, 33, 34. Each of a plurality of sense amplifiers 41, 42, 43, 44 is connected to two bit-lines 21, 22, 23, 24, 25, 26, 27, 28. Each bit-line 21, 22, 23, 24, 25, 26, 27, 28 is connected to one sense amplifier 41, 42, 43, 44.

A plurality of switches 451, 452, 453, 454 are provided switchably connecting respective pairs of bit-lines 21, 22, 23, 24, 25, 26, 27, 28. A controller 461 is operatively connected to the switches 451, 452, 453, 454 via control lines 463, 464 and controls the switches 451, 452, 453, 454. Similar to the memory circuit described above with reference to FIG. 3, two bit-lines connected to any one of the plurality of switches are connected to two sense amplifiers 441, 442, 443, 444 which are arranged at opposite sides of the array.

The memory circuit 410 described with reference to FIG. 4 differs from the memory device described above with reference to FIG. 3 in that bit-lines connected to the same sense amplifier 441, 442, 443, 444 are not next neighbors to each other. Rather, the bit-lines 21, 22, 23, 24, 25, 26, 27, 28 are alternatingly connected to sense amplifiers 441, 442, 443, 444 arranged at different (more particular: opposite) sides or edges of the array. Between any pair of bit-lines 21, 23; 25, 27 connected to a sense amplifier 441, 442 arranged at a first side of the array, there is arranged a bit-line 22, 26 connected to a sense amplifier 443, 444 arranged at a second (opposite) side of the array; and between any pair of bit-lines 22, 24; 26, 28 connected to a sense amplifier 443, 444 arranged at the second side of the array, there is arranged a bit-line 23, 27 connected to a sense amplifier 441, 442 arranged at the first side of the array.

As a result of this particular topology and as a further difference from the memory circuit described above with reference to FIG. 2, each switch 451, 452, 453, 454 is connected to a pair of bit-lines (23, 24; 27, 28; 21, 22; 25, 26 which are next neighbors to each other.

The operation of the memory circuit 410 displayed in FIG. 4 is quite similar to the operation of the memory circuits described above with reference to FIGS. 1 and 3. In particular, the reference potentials for the detection of the resistive storage states of the memory cells are generated as arithmetic means of two predetermined potentials as described above.

The memory circuit 410 described with reference to FIG. 4 provides a number of advantages, in particular when compared to the memory circuit described above with reference to FIG. 1. In particular, only one control line 463, 464 needs to be provided at each side of the array. This reduces the required chip area and simplifies the design of the control lines 463, 464, thereby reducing the costs of design and production.

As a further advantage, there are no cross points of the wires connecting the switches 451, 452, 453, 454 to the bit-lines 21, 22, 23, 24, 25, 26, 27, 28 (confer the above discussion with reference to FIG. 3).

As has been already mentioned, the FIGS. 1 to 4 display schematic circuit diagrams. In particular, the number of memory cells 12, the number of bit-lines 21, 22, 23, 24, 25, 26, 27, 28 and the number of word-lines 31, 32, 33, 34 can be (and typically are) much bigger than displayed in FIGS. 1 through 4.

Although the present invention is particularly advantageous for CBRAM and other memory circuits with resistive storage elements and with sense amplifiers of the voltage sensitive type, the present invention is also advantageous for other types of memory circuits or other storage technologies, respectively. In particular, the present invention is advantageous for CBRAMs with charge sensitive or current sensitive sense amplifiers and for other (non CBRAM) types of memory circuits in which potentials or charges are compared by differential amplifiers during a reading, writing or refreshing procedure and in which an arithmetic mean potential or charge is used as a reference potential or reference charge, respectively.

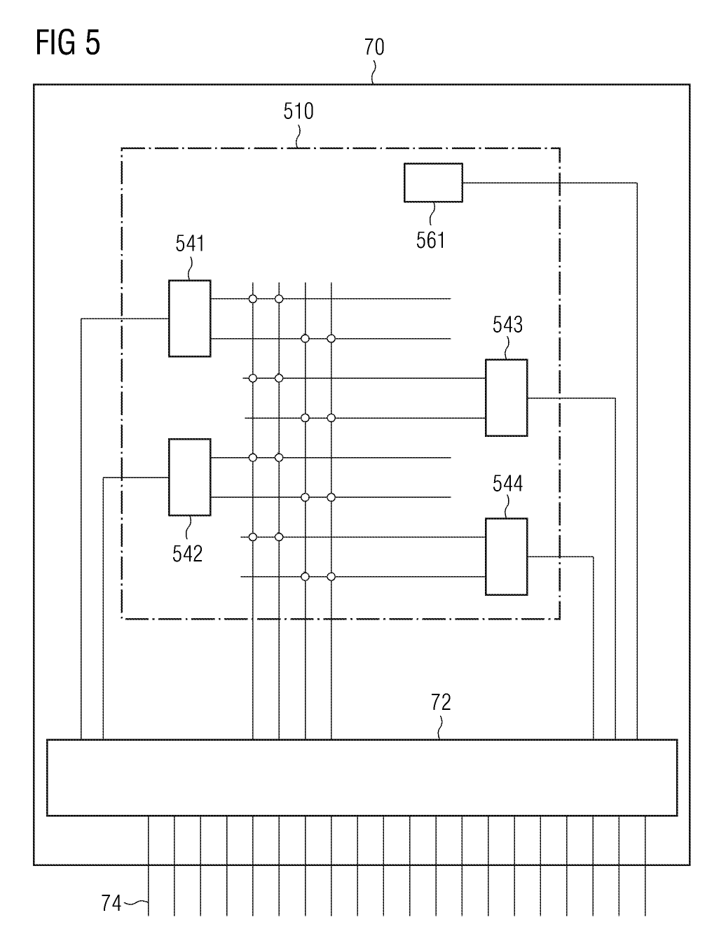

FIG. 5 is a schematic circuit diagram of a microelectronic device 70 comprising a memory circuit as described above with reference to FIG. 3, FIG. 4 or one of the alternatives or variants also described above. Further, the microelectronic device 70 comprises other circuits which are represented in a schematic and summarizing manner by a structure with the reference numeral 72. These other circuits are operatively connected to the word-lines 31, 32, 33, 34, the sense amplifiers 541, 542, 543, 544 and the controller 561. Furthermore, the microelectronic device 70 provides a number of input and/or output lines 74 connected to the other circuits 72 (and/or to the memory circuit 510).

The microelectronic device 70 may be a processor or microcontroller with cache or other internal memory provided by the memory circuit 510 or any other microelectronic device with one or several memory circuits 510.

In one embodiment, the microelectronic device 70 is a memory device with a plurality of memory circuits 510, each of which comprises an array of memory cells. In this case the other circuits 72 schematically represent input and output amplifiers, registers, address decoders etc.

Alternatively, the microelectronic device 70 is an embedded system formed for an application in a mobile communication system (for example a mobile telephone) or a mobile information technology system (for example a handheld computer, a notebook computer or a laptop computer), for automotive or any other applications.

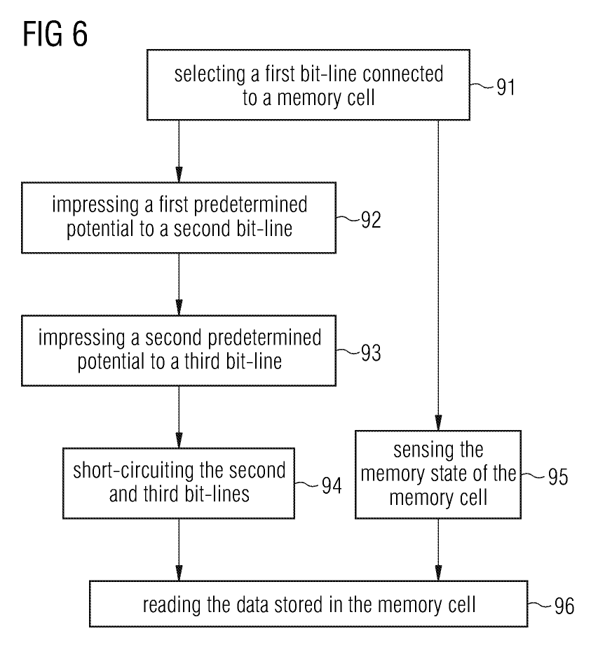

FIG. 6 is a schematic flow chart of a method according to another embodiment of the present invention. In a first step 91, a first bit-line connected to a memory cell to be read or written or refreshed is selected, wherein the first bit-line is connected to a first sense amplifier. In a second step 92, a first predetermined potential is applied to a second bit-line connected to the first sense amplifier. In one embodiment, the second bit-line is arranged adjacent to the first bit-line, i.e. the first and the second bit-lines are next neighbors to each other.

In a third step 93, a second predetermined potential is applied to a third bit-line connected to a second sense amplifier. When referring to a memory circuit as described above with reference to FIG. 3, the third bit-line is also adjacent to the first bit-line, i.e. the first bit-line is arranged between the second and the third bit-lines, and the second and the third bit-lines are next neighbors to the first bit-line. When referring to the memory circuit described above with reference to FIG. 4, the second sense amplifier is arranged at a side of the array of memory cells opposite to the side at which the first sense amplifier is arranged.

In a fourth step 94, the second and the third bit-lines are short-circuited.

In a fifth step 95, the memory state of the memory cell connected to the first bit-line is sensed by activating a respective word-line, thereby connecting the storage element of the memory cell to the first bit-line. Although this step may be conducted after the fourth step 94, the fifth step 95 is preferably conducted simultaneously to the fourth steps 94 or simultaneously to the second through fourth steps 92, 93, 94.

In a sixth step 96, the data stored in the memory cell is read by comparing the voltages or potentials of the first and second bit-lines.

The preceding description only describes advantageous exemplary embodiments of the invention. The features disclosed therein and the claims and the drawings can, therefore, be essential for the realization of the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. A memory circuit, comprising:
a plurality of parallel bit-lines connected to a plurality of memory cells;
a plurality of sense amplifiers connected to the bit-lines; and
a plurality of switches, wherein each switch is connected to a respective pair of bit-lines of the plurality of bit-lines for switchably short-circuiting the respective pair of bit-lines, wherein the bit-lines of the respective pair of bit-lines are connected to two different sense amplifiers, and wherein the bit-lines of the respective pair of bit-lines are adjacent to a further bit-line disposed between the bit-lines of the respective pair of bit-lines.

2. The memory circuit of claim 1,
wherein the plurality of memory cells are arranged in a two-dimensional array,
wherein a first group of bit-lines of the plurality of bit-lines is connected solely to sense amplifiers arranged at a first side of the array,
wherein a second group of bit-lines out of the plurality of bit-lines is connected solely to sense amplifiers arranged at a second side of the array, and
wherein each respective pair of bit-lines which are connected to a switch of the plurality of switches includes one bit-line from the first group of bit-lines and one bit-line from the second group of bit-lines.

3. The memory circuit of claim 1, further comprising:
a controller connected to the plurality of switches for controlling the plurality of switches.

4. The memory circuit of claim 3, wherein the controller is configured to close a switch connected to a respective pair of bit-lines when both bit-lines out of the respective pair of bit-lines are not connected to a memory cell to be read or written or refreshed.

5. The memory circuit of claim 4, wherein the controller is configured to connect the respective pair of bit-lines to two different potentials before short-circuiting the respective pair of bit-lines.

6. The memory circuit of claim 1, wherein each of the plurality of memory cells comprises a resistive storage element.

7. A memory circuit, comprising:
a plurality of memory cells arranged in a two-dimensional array;
a plurality of parallel bit-lines connected to the plurality of memory cells;
a plurality of sense amplifiers connected to the plurality of bit-lines; and
a plurality of switches, each of which is connected to a respective pair of bit-lines of the plurality of bit-lines for switchably short-circuiting the respective pair of bit-lines,
wherein a first group of bit-lines of the plurality of bit-lines is connected solely to sense amplifiers arranged at a first side of the array,
wherein a second group of bit-lines of the plurality of bit-lines is connected solely to sense amplifiers arranged at a second side of the array, and
wherein each respective pair of bit-lines connected to a switch out of the plurality of switches includes one bit-line out of the first group of bit-lines and one bit-line out of the second group of bit-lines.

8. The memory circuit of claim 7, wherein the bit-lines of each respective pair of bit-lines connected to a switch out of the plurality of switches are adjacent to each other.

9. The memory circuit of claim 7, wherein each of the plurality of memory cells comprises a resistive storage element.

10. A microelectronic device, comprising a memory circuit, wherein the memory circuit comprises:
a plurality of parallel bit-lines connected to a plurality of memory cells;
a plurality of sense amplifiers connected to the bit-lines; and
a plurality of switches, wherein each switch is connected to a respective pair of bit-lines of the plurality of bit-lines for switchably short-circuiting the respective pair of bit-lines, wherein the bit-lines of the respective pair of bit-lines are connected to two different sense amplifiers, and wherein the bit-lines of the respective pair of bit-lines are adjacent to a further bit-line disposed between the bit-lines of the respective pair of bit-lines.

11. The microelectronic device of claim 10, wherein the microelectronic device is a memory device.

12. The microelectronic device of claim 10, further comprising one of a processor and an information processing circuit.

13. The microelectronic device of claim 12, wherein the microelectronic device is an embedded system formed for one of a mobile application and an automotive application.

14. A microelectronic device, comprising a memory circuit, wherein the memory circuit comprises:
a plurality of memory cells arranged in a two-dimensional array;
a plurality of parallel bit-lines connected to the plurality of memory cells;
a plurality of sense amplifiers connected to the plurality of bit-lines; and
a plurality of switches, each of which is connected to a respective pair of bit-lines of the plurality of bit-lines for switchably short-circuiting the respective pair of bit-lines,
wherein a first group of bit-lines of the plurality of bit-lines is connected solely to sense amplifiers arranged at a first side of the array,
wherein a second group of bit-lines of the plurality of bit-lines is connected solely to sense amplifiers arranged at a second side of the array, and
wherein each respective pair of bit-lines connected to a switch out of the plurality of switches includes one bit-line out of the first group of bit-lines and one bit-line out of the second group of bit-lines.

15. The microelectronic device of claim 14, wherein the microelectronic device is a memory device.

16. A method of operating a memory circuit, the method comprising:
selecting a first bit-line connected to a memory cell to be read from, written to or refreshed, wherein the first bit-line is connected to a first sense amplifier;
applying a first predetermined potential to a second bit-line, wherein the second bit-line and the first bit-line are adjacent to each other, and wherein the second bit-line is connected to the first sense amplifier;
applying a second predetermined potential to a third bit-line, wherein the third bit-line and the first bit-line are adjacent to each other, and wherein the third bit-line is connected to a second sense amplifier;
short-circuiting the second and third bit-lines;
sensing the memory state of the memory cell to be read from or written to; and
reading data from the memory cell.

17. A method of operating a memory circuit comprising an array of memory cells, the method comprising:
selecting a first bit-line connected to a memory cell to be read from, written to or refreshed, wherein the first bit-line is connected to a first sense amplifier arranged at a first side of the array;
applying a first predetermined potential to a second bit-line connected to the first sense amplifier;
applying a second predetermined potential to a third bit-line connected to a second sense amplifier arranged at a second side of the array;
short-circuiting the second and third bit-lines;
sensing the memory state of the memory cell to be read from or written to; and
reading data from the memory cell.
